(19) United States
(12) Patent Application Publication
(10) Pub. No.: US 2012/0204961 A1
(43) Pub. Date: Aug. 16, 2012

(54) ORGANIC PHOTOVOLTAIC CELL

(76) Inventors: Takehito Kato, Tochigi (JP); Toshihiro Ohnishi, Ibaraki (JP)

(21) Appl. No.: 13/503,980

(22) PCT Filed: Oct. 26, 2010
(86) PCT No.: PCT/JP2010/068935

§ 371 Date: Apr. 25, 2012

(30) Foreign Application Priority Data
Oct. 30, 2009 (JP) 2009-250581

(51) Int. Cl. H01L 51/42

(52) U.S. Cl. 136/263

(57) ABSTRACT

Provided is an organic photovoltaic cell having a long lifetime. An organic photovoltaic cell 100 includes a first electrode 2, a second electrode 6, an active layer 4 that is provided between the first electrode 2 and the second electrode 6 and that can generate a charge by incident light, a first ultraviolet absorbing layer 9 comprising a first ultraviolet absorber that can absorb ultraviolet light having a wavelength not longer than a first absorption wavelength edge, and a second ultraviolet absorbing layer 9 comprising a second ultraviolet absorber that can absorb ultraviolet light having a wavelength not longer than a second absorption wavelength edge having a wavelength shorter by 10 nm or larger than that of the first absorption wavelength edge.

### TECHNICAL FIELD

The present invention relates to an organic photovoltaic cell.

### BACKGROUND ART

A photovoltaic cell is a cell that can convert light energy into electric energy and an example thereof is a solar cell. The solar cell typically includes a silicon solar cell. However, the silicon solar cell requires a high vacuum environment and a high pressure environment in the production process to increase production cost. On this account, an organic solar cell has been drawing attention because the production cost of the organic solar cell is lower than that of the silicon solar cell.

However, the organic solar cell uses an organic material, which is likely to deteriorate due to ultraviolet light (UV) and the like, and thus the organic solar cell tends to have shorter lifetime than that of the silicon solar cell. Hence, in order to elongate the lifetime of the organic solar cell, various techniques have been developed. For example, Patent Document 1 discloses a structure, wherein an UV cut film for an organic solar cell is provided in order to block ultraviolet light.

### RELATED ART DOCUMENTS

### Patent Literature

Patent Document 1: JP No. 2007-67115 A

### SUMMARY

Blocking incident ultraviolet light by an UV cut film can suppress deterioration of the organic material due to the ultraviolet light to elongate the lifetime of the organic solar cell. However, the technique according to Patent Document 1 insufficiently elongates the lifetime, and there has been a demand for techniques that can further elongate the lifetime of the organic solar cell. The demand has been also common to organic photovoltaic cells other than the organic solar cell.

In view of the above problems, the present invention provides an organic photovoltaic cell having a longer lifetime.

The inventors of the present invention have carried out intensive studies in order to solve the problems; as a result, they have found that, by providing an ultraviolet absorbing layer using two or more ultraviolet absorbers having absorption wavelengths different to each other in an organic photovoltaic cell, the organic photovoltaic cell can be effectively protected from ultraviolet light to elongate the lifetime. In this manner, the present invention has been accomplished.

Specifically, the present invention is as follows.
[1] An organic photovoltaic cell comprising:
   a first electrode;
   a second electrode;
   an active layer provided between the first electrode and the second electrode and capable of generating a charge by incident light;
   a first ultraviolet absorbing layer comprising a first ultraviolet absorber capable of absorbing ultraviolet light having a wavelength not longer than a first absorption wavelength edge; and
   a second ultraviolet absorbing layer comprising a second ultraviolet absorber capable of absorbing ultraviolet light having a wavelength not longer than a second absorption wavelength edge having a wavelength shorter by 10 nm or larger than that of the first absorption wavelength edge.
[2] The organic photovoltaic cell according to [1], wherein the first ultraviolet absorbing layer or the second ultraviolet absorbing layer, the first electrode, the active layer, and the second electrode are arranged in this order.
[3] The organic photovoltaic cell according to [2], comprising an organic layer comprising an organic material between the first electrode and the first ultraviolet absorbing layer or the second ultraviolet absorbing layer.

### BRIEF DESCRIPTION OF DRAWINGS

FIG. 1 is a schematic cross-sectional view of an organic photovoltaic cell of a first embodiment of the present invention.

FIG. 2 is a schematic cross-sectional view of an organic photovoltaic cell of a second embodiment of the present invention.

FIG. 3 is a schematic cross-sectional view of an organic photovoltaic cell of a third embodiment of the present invention.

### EXPLANATIONS OF LETTERS OR NUMERALS

1 substrate

2 first electrode

3 functional layer

4 active layer

5 functional layer

6 second electrode

7 sealer layer

8 substrate

9 ultraviolet absorbing layer

10 first ultraviolet absorbing layer

11 second ultraviolet absorbing layer

12 first ultraviolet absorbing layer

13 second ultraviolet absorbing layer

100, 200, 300 organic photovoltaic cell

### DESCRIPTION OF EMBODIMENTS

Hereinafter, the present invention will be described in detail with reference to embodiments, exemplary substances, and the like, but the present invention is not limited thereto, and any changes and modifications may be made in the present invention without departing from the gist of the present invention. In the present invention, “ultraviolet light” refers to light having a wavelength of 400 nm or less.

### [1. Outline]

The organic photovoltaic cell of the present invention comprises a first electrode, a second electrode, and an active layer that is provided between the first electrode and the second electrode and that can generate a charge by incident light. Hence, the layers are arranged in the order of the first electrode, the active layer, and the second electrode. The organic photovoltaic cell of the present invention further comprises a first ultraviolet absorbing layer comprising a first ultraviolet absorber that can absorb ultraviolet light having a wavelength not longer than a first absorption wavelength edge and a second ultraviolet absorbing layer comprising a second ultraviolet absorber that can absorb ultraviolet light having a wavelength not longer than a second absorption wavelength edge having a wavelength shorter by 10 nm or larger than that of the first absorption wavelength edge. The organic photovoltaic cell of the present invention can absorb ultraviolet lights having different wavelength bands to each other in the first ultraviolet absorbing layer and the second ultraviolet absorbing layer. Thus, the amount of ultraviolet light input to the active layer can be reduced than that of a conventional cell to suppress deterioration of an organic material contained in the active layer due to ultraviolet light. Therefore, the organic photovoltaic cell of the present invention is effectively protected from ultraviolet light; hence, the organic photovoltaic cell can maintain stable photovoltaic conversion characteristics for a long time to elongate the lifetime.

The organic photovoltaic cell of the present invention may have other layers in addition to the first electrode, the active layer, the second electrode, the first ultraviolet absorbing layer, and the second ultraviolet absorbing layer. For example, the organic photovoltaic cell of the present invention may have a functional layer between the first electrode and the active layer and may have a functional layer between the active layer and the second electrode.

The organic photovoltaic cell of the present invention usually comprises a substrate and, on the substrate, layers (for example, the first electrode, the active layer, the second electrode, the first ultraviolet absorbing layer, the second ultraviolet absorbing layer, and the functional layers) are stacked to constitute the organic photovoltaic cell of the present invention.

### [2. Substrate]

The substrate is a member serving as a support of the organic photovoltaic cell of the present invention. The substrate usually employs a member that is not chemically changed during the formation of the electrode and the formation of an organic material layer. Examples of a material for the substrate may include glass, a plastic, a polymer film, and silicon. The materials for the substrate may be used alone or in combination of two or more of them at any ratio.

Usually, a transparent or translucent member is used as the substrate, but an opaque substrate may be used. However, when the opaque substrate is used, the electrode opposite to the opaque substrate (namely, either the first electrode or the second electrode which is the electrode more distant from the opaque substrate) is preferably transparent or translucent.

### [3. First Electrode and Second Electrode]

Of the first electrode and the second electrode, one is an anode and the other is a cathode. At least one of the first electrode and the second electrode is preferably transparent or translucent so that light can readily enter the active layer placed between the first electrode and the second electrode. The organic photovoltaic cell of the present invention can reduce ultraviolet light contained in light that passes through the first ultraviolet absorbing layer and the second ultraviolet absorbing layer and enters the active layer. Thus, the first electrode is preferably transparent or translucent when the first ultraviolet absorbing layer or the second ultraviolet absorbing layer is provided on a surface closer to the first electrode than the active layer, while the second electrode is preferably transparent or translucent when the first ultraviolet absorbing layer or the second ultraviolet absorbing layer is provided on a surface closer to the second electrode than the active layer.

Examples of the transparent or translucent electrode may include an electrically conductive metal oxide film and a translucent metal thin film. Examples of a material for the transparent or translucent electrode may include: films formed using electrically conductive materials such as indium oxide, zinc oxide, tin oxide, complexes of them such as indium tin oxide (ITO), indium zinc oxide (IZO), and NESA; gold; platinum; silver; and copper. Among them, ITO, indium zinc oxide, and tin oxide are preferred.

As the material for the transparent or translucent electrode, an organic material may also be used. Examples of the organic material usable as the material for the electrode may include electrically conductive polymers such as polyaniline, a derivative thereof, polythiophene, and a derivative thereof.

Examples of a material for the opaque electrode may include a metal and an electrically conductive polymer. Specific examples of the material may include: metals such as lithium, sodium, potassium, rubidium, cesium, magnesium, calcium, strontium, barium, aluminum, scandium, vanadium, zinc, yttrium, indium, cerium, samarium, europium, terbium, and ytterbium; an alloy of two or more of the metals; an alloy of one or more of the metals and one or more of metals selected from a group consisting of gold, silver, platinum, copper, manganese, titanium, cobalt, nickel, tungsten, and tin; graphite; a graphite intercalation compound; polyaniline and a derivative thereof; and polythiophene and a derivative thereof. Specific examples of the alloy may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The materials for the electrode may be used alone or in combination of two or more of them at any ratio.

Each of the first electrode and the second electrode has a varied thickness depending on the material type of the electrode. The thickness is preferably 500 nm or smaller and more preferably 200 nm or smaller in order to increase transmittance of light and to suppress electric resistance. The thickness has no lower limit but is usually 10 nm or larger.

Examples of the formation method of the first electrode and the second electrode may include a vacuum deposition method, a sputtering method, an ion plating method, and a plating method. For the formation of the first electrode and the second electrode from, for example, an electrically conductive polymer, a coating method may be employed.

### [4. Active Layer]

The active layer is a layer capable of generating a charge by incident light and usually comprises a p-type semiconductor that is an electron-donor compound and an n-type semiconductor that is an electron-acceptor compound. The organic photovoltaic cell of the present invention uses organic compounds as at least one of the p-type semiconductor and the n-type semiconductor, usually as both semiconductors, and hence is called the “organic” photovoltaic cell. The p-type semiconductor and the n-type semiconductor are relatively determined by the energy level of each energy state of the semiconductors.

In the active layer, the charge is supposed to be generated in the following manner. When light energy input to the active layer is absorbed in one or both of the n-type semiconductor and the p-type semiconductor, an exinton comprising an electron and a hole bonded to each other is formed. The formed exciton is transferred to reach to a heterojunction interface where the n-type semiconductor is in contact with the p-type semiconductor. The electron and hole are separated due to corresponding differences of the HOMO (highest occupied molecular orbital) energies and the LUMO (lowest unoccupied molecular orbital) energies at the heterojunction interface, thus generating charges (electron and hole) that can independently move. The generated charges are transferred to the corresponding electrodes to be able to be extracted from the organic photovoltaic cell of the present invention as electric energy (current) to the exterior.

The active layer may have a single layer structure comprising one layer alone or may have a stacked structure comprising two or more layers as long as the active layer can generate a charge by incident light. Examples of the layer composition of the active layer include the following compositions. However, the layer composition of the active layer is not limited to the examples.

Layer composition (i): the active layer having a stacked structure comprising a layer comprising the p-type semiconductor and a layer comprising the n-type semiconductor.

Layer composition (ii): the active layer having a single layer structure comprising the p-type semiconductor and the n-type semiconductor.

Layer composition (iii): the active layer having a stacked structure comprising a layer comprising the p-type semiconductor, a layer comprising the p-type semiconductor and the n-type semiconductor, and a layer comprising the n-type semiconductor.

Examples of the p-type semiconductor may include a pyrazoline derivative, an arylamine derivative, a stilbene derivative, a triphenyldiamine derivative, oligothiophene and a derivative thereof, polyvinylcarbazole and a derivative thereof, polysilane and a derivative thereof, a polysiloxane derivative having an aromatic amine on a side chain or the main chain, polyaniline and a derivative thereof, polythiophene and a derivative thereof, polypyrrole and a derivative thereof, poly(phenylene vinylene) and a derivative thereof, and poly(thienylene vinylene) and a derivative thereof.

An organic macromolecular compound having a structural unit represented by the following structural formula (1) is preferred as the p-type semiconductor.

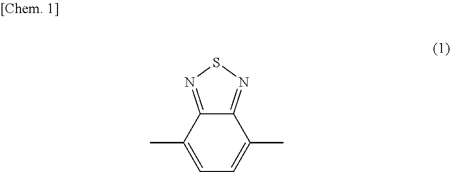

The organic macromolecular compound is more preferably a copolymer of the compound having the structural unit represented by the structural formula (1) and a compound represented by the following structural formula (2).

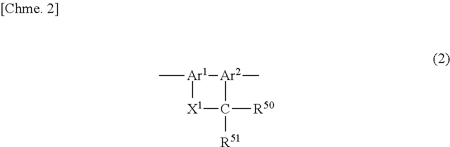

[In Formula (2), Ar¹ and Ar² are the same as or different from each other and represent a trivalent heterocyclic group. X¹ represents —O—, —S—, —C(═O)—, —S(═O)—, —SO₂—, —Si(R³) (R⁴) —N(R⁵)—, —B(R⁶) —P(R⁷)—, or —P(═O) (R⁸)—. R³, R⁴, R⁵, R⁶, R⁷, and R⁸ are the same as or different from each other and represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having six or more carbon atoms, an alkyloxy group having six or more carbon atoms, an alkylthio group having six or more carbon atoms, an aryl group having six or more carbon atoms, an aryloxy group having six or more carbon atoms, an arylthio group having six or more carbon atoms, an arylalkyl group having seven or more carbon atoms, an arylalkyloxy group having seven or more carbon atoms, an arylalkylthio group having seven or more carbon atoms, an acyl group having six or more carbon atoms, or an acyloxy group having six or more carbon atoms. X¹ and Ar² are bonded to vicinal positions of the heterocyclic ring comprised in Ar¹, and C(R⁵⁰)(R⁵¹) and Ar¹ are bonded to vicinal positions of the heterocyclic ring comprised in Ar².]

The p-type semiconductors may be used alone or in combination of two or more of them at any ratio.

Examples of the n-type semiconductor may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, metal complexes of 8-hydroxyquinoline and a derivative thereof, polyquinoline and a derivative thereof, polyquinoxaline and a derivative thereof, polyfluorene and a derivative thereof, fullerenes such as C₆₀ and a derivative thereof, a phenanthrene derivative such as bathocuproine, a metal oxide such as titanium dioxide, and a carbon nanotube. Among them, titanium dioxide, a carbon nanotube, a fullerene, and a fullerene derivative are preferred, and a fullerene and a fullerene derivative are especially preferred.

Examples of the fullerene may include C₆₀ fullerene, C₇₀ fullerene, C₇₆ fullerene, C₇₈ fullerene, and C₈₄ fullerene.

Examples of the fullerene derivative may include derivatives of C₆₀, C₇₀, C₇₆, C₇₈, and C₈₄. Specific examples of the fullerene derivative may include compounds having the following structures.

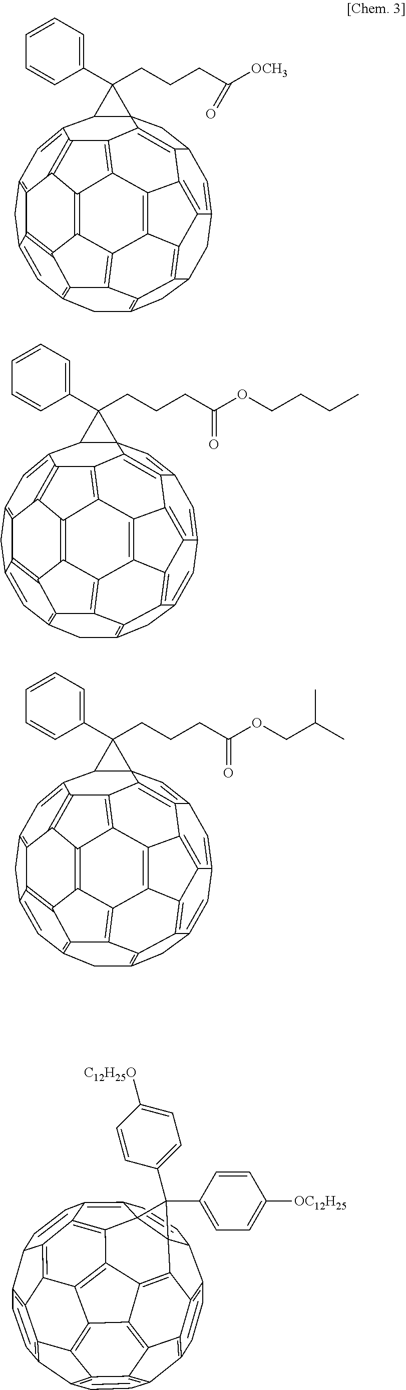

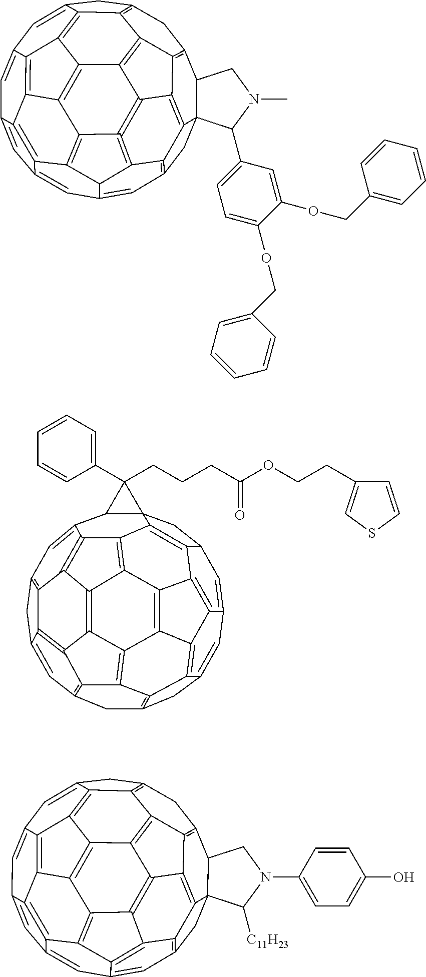

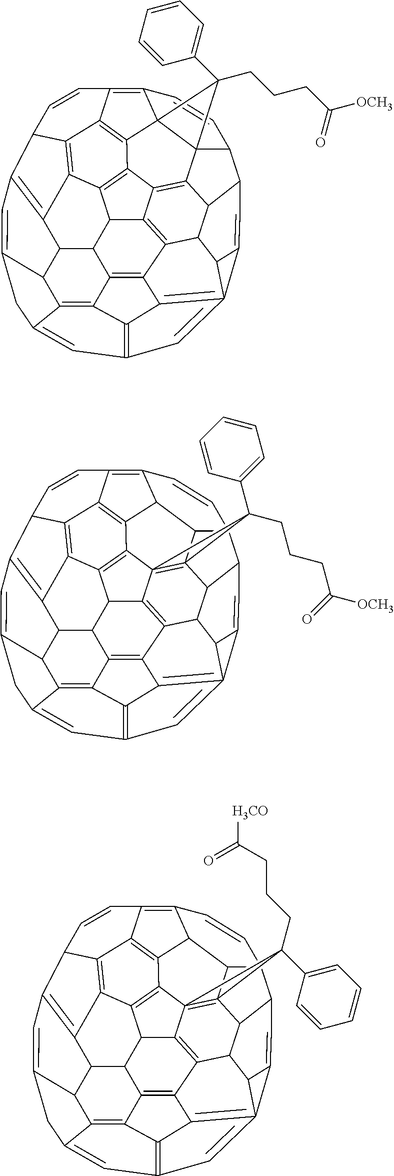

Other examples of the fullerene derivative may include [6,6]-phenyl C₆₁ butyric acid methyl ester (C60PCBM), [6,6]-phenyl C₇₁ butyric acid methyl ester (C70PCBM), [6,6]-phenyl C₈₅ butyric acid methyl ester (C84PCBM), and [6,6]-thienyl C₆₁ butyric acid methyl ester.

The n-type semiconductor may be used alone or in combination of two or more of them at any ratio.

The active layer may comprise the p-type semiconductor and the n-type semiconductor at any ratio as long as the effect of the present invention is not impaired. For example, in a layer comprising both of the p-type semiconductor and the n-type semiconductor in the layer compositions (i) and (iii), the n-type semiconductor is preferably comprised in an amount of 10 parts by weight or more and more preferably 20 parts by weight or more, and is preferably comprised in an amount of 1,000 parts by weight or less and more preferably 500 parts by weight or less, with respect to 100 parts by weight of the p-type semiconductor.

The active layer usually has a thickness of 1 nm or larger, preferably 2 nm or larger, more preferably 5 nm or larger, and particularly preferably 20 nm or larger, and usually has a thickness of 100 ⱼam or smaller, preferably 1,000 nm or smaller, more preferably 500 nm or smaller, and particularly preferably 200 nm or smaller.

The active layer may be formed by any method. Examples of the method may include a film formation method from a liquid composition comprising a material (for example, one or both of the p-type semiconductor and the n-type semiconductor) for the active layer; and a film formation method by a gas phase film formation method such as a physical vapor deposition method (PVD method) including a vacuum deposition method and a chemical vapor deposition method (CVD method). Among them, the film formation method from a liquid composition is preferred because a film is readily formed to reduce the cost.

In the film formation method from a liquid composition, a liquid composition is prepared, the liquid composition is applied onto a desired area to form a film as the active layer.

The liquid composition usually comprises a material for the active layer and a solvent. When the solvent is contained, the liquid composition may be a dispersion liquid dispersing the material for the active layer in the solvent, but is preferably a solution dissolving the material for the active layer in the solvent. Hence, the solvent to be used is preferably a solvent that can dissolve the material for the active layer. Examples of the solvent may include: unsaturated hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; and ether solvents such as tetrahydrofuran and tetrahydropyran. The solvents may be used alone or in combination of two or more of them at any ratio.

Each concentration of the p-type semiconductor and the n-type semiconductor in the liquid composition is usually 0.1% by weight or more with respect to a solvent.

Examples of the film formation method of the liquid composition may include coating methods such as a spin coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet printing method, a dispenser printing method, a nozzle coating method, and a capillary coating method. Among them, a spin coating method, a flexographic printing method, a gravure printing method, an inkjet printing method, and a dispenser printing method are preferred.

After the film formation of the liquid composition, as necessary, a process such as a process of drying the formed film to remove the solvent is performed, and consequently the active layer is obtained.

For an active layer having a stacked structure comprising two or more layers, for example, each layer constituting the active layer may be sequentially stacked by the aforementioned method.

### [5. First Ultraviolet Absorbing Layer and Second Ultraviolet Absorbing Layer]

The organic photovoltaic cell of the present invention comprises a first ultraviolet absorbing layer and a second ultraviolet absorbing layer in addition to the active layer, the first electrode, and the second electrode. The first ultraviolet absorbing layer is a layer that can absorb ultraviolet light having a wavelength not longer than a first absorption wavelength edge and can block the ultraviolet light. In order to absorb such ultraviolet light having a wavelength not longer than the first absorption wavelength edge, the first ultraviolet absorbing layer contains a first ultraviolet absorber that can absorb ultraviolet light having a wavelength not longer than the first absorption wavelength edge. Meanwhile, the second ultraviolet absorbing layer is a layer that can absorb ultraviolet light having a wavelength not longer than a second absorption wavelength edge and can block the ultraviolet light. In order to absorb such ultraviolet light having a wavelength not longer than the second absorption wavelength edge, the second ultraviolet absorbing layer contains a second ultraviolet absorber that can absorb ultraviolet light having a wavelength not longer than the second absorption wavelength edge.

The second absorption wavelength edge has a wavelength shorter than that of the first absorption wavelength edge. The difference between the first absorption wavelength edge and the second absorption wavelength edge is usually 10 nm or larger, preferably 15 nm or larger, and more preferably 20 nm or larger. On this account, the first ultraviolet absorber and the second ultraviolet absorber can absorb ultraviolet lights having different wavelength bands. Therefore, the organic photovoltaic cell of the present invention that comprises the first ultraviolet absorbing layer and the second ultraviolet absorbing layer can block ultraviolet light having a wider wavelength band than that of a conventional cell to effectively suppress deterioration of an organic material contained in the active layer due to ultraviolet light.

The first absorption wavelength edge refers to the longest wavelength in a wavelength band where ultraviolet light passing through a film of the first ultraviolet absorber having a thickness of 50 μm has a transmittance of 80% or smaller, while the second absorption wavelength edge refers to the longest wavelength in a wavelength band where ultraviolet light passing through a film of the second ultraviolet absorber having a thickness of 50 μm has a transmittance of 80% or smaller.

The first ultraviolet absorbing layer and the second ultraviolet absorbing layer may be the same layer and may be different layers. The first ultraviolet absorbing layer and the second ultraviolet absorbing layer being the same layer means that one layer comprises the first ultraviolet absorber and the second ultraviolet absorber and that the layer serves as both the first ultraviolet absorbing layer and the second ultraviolet absorbing layer. The first ultraviolet absorbing layer and the second ultraviolet absorbing layer being different layers means that a layer comprising the first ultraviolet absorber and a layer comprising the second ultraviolet absorber are independently provided. However, in order to increase design flexibility of the organic photovoltaic cell of the present invention, the first ultraviolet absorbing layer and the second ultraviolet absorbing layer are preferably provided as different layers.

The first ultraviolet absorbing layer and the second ultraviolet absorbing layer may be formed at any positions as long as the effect of the present invention is not significantly impaired. Specifically, preferred example of the position may include a structure in which the first ultraviolet absorbing layer or the second ultraviolet absorbing layer (hereinafter, appropriately abbreviated as “external ultraviolet absorbing layer”), the first electrode, the active layer, and the second electrode are arranged in this order. Such a structure leads the external ultraviolet absorbing layer to be provided on an outside of the first electrode (a position far from the active layer); therefore, the first electrode can be covered from the outside with the external ultraviolet absorbing layer to increase sealing properties of the organic photovoltaic cell. Furthermore, when the external ultraviolet absorbing layer is provided at the preferred position, light is usually applied from a side closer to the first electrode than the active layer to the organic photovoltaic cell. The applied light is input through the external ultraviolet absorbing layer to the active layer, while light that has not been used for photovoltaic conversion in the active layer is reflected from the second electrode and then is output through the external ultraviolet absorbing layer to the exterior of the organic photovoltaic cell. Hence, the external ultraviolet absorbing layer that causes light scattering and the like can trap light in the organic photovoltaic cell to increase the photovoltaic conversion efficiency. In the description of the preferred position, the external ultraviolet absorbing layer refers to a layer of the first ultraviolet absorbing layer and the second ultraviolet absorbing layer that is provided on an outside of the first electrode. The first electrode may be an anode or may be a cathode. One or both of the first ultraviolet absorbing layer and the second ultraviolet absorbing layer may also be provided on an outside of the second electrode.

As the first ultraviolet absorber and the second ultraviolet absorber, an organic material may be used and an inorganic material may be used. For the first ultraviolet absorber and the second ultraviolet absorber, examples of the organic material may include benzophenone ultraviolet absorbers, benzotriazole ultraviolet absorbers, triazine ultraviolet absorbers, and phenyl salicylate ultraviolet absorbers. Among them, preferred examples specifically may include 2,4-dihydroxy-benzophenone, 2-hydroxy-4-methoxybenzophenone, 4-dodecyloxy-2-hydroxybenzophenone, 2-hydroxy-4-methoxy-5-sulfobenzophenone, 2-(2′-hydroxy-5-methylphenyl)benzotriazole, 2-(2′-hydroxy-3′, 5′-di-tert-butylphenyl)benzotriazole, phenyl salicylate, p-octylphenyl salicylate, and p-tert-butylphenyl salicylate. Examples of the first ultraviolet absorber and second ultraviolet absorber composed of the inorganic material may include titanium dioxide and zinc oxide. Among them, the inorganic materials are preferably used.

As the first ultraviolet absorber and the second ultraviolet absorber, a wavelength-conversion material that can perform wavelength-conversion of absorbed ultraviolet light into light having a longer wavelength than that of the absorbed ultraviolet light may be used. When the wavelength-conversion material is used as at least some of the first ultraviolet absorber and the second ultraviolet absorber, the light that has been subjected to wavelength-conversion and that has a longer wavelength is input to the active layer to be used as the light energy for charge generation in the active layer. Thus, the use of the wavelength-conversion material as the first ultraviolet absorber and the second ultraviolet absorber can reduce ultraviolet light input to the active layer to suppress the deterioration of an organic material as well as can increase the charge generation amount in the active layer to improve the photovoltaic conversion efficiency. Examples of the light that have been subjected to wavelength-conversion from the absorbed ultraviolet light may include visible light, near infrared light, and infrared light. A wavelength-conversion material capable of wavelength-conversion of the ultraviolet light into the visible light is preferred in order to increase the photovoltaic conversion efficiency.

Examples of the wavelength-conversion material may include a phosphor. The phosphor is usually a material that can absorb excitation light to emit fluorescence having longer wavelength than that of the excitation light. Hence, for the phosphor used as the first ultraviolet absorber and the second ultraviolet absorber, a phosphor capable of absorbing ultraviolet light as the excitation light and capable of emitting fluorescence having such wavelength available for the charge generation in the active layer may be used.

Among the phosphors, examples of the organic phosphor may include a rare earth complex. The rare earth complex is a phosphor excellent in fluorescent characteristics, and specific examples may include a [Tb(bpy)₂]Cl₃ complex, an [Eu(phen)₂]Cl₃ complex, and a [Tb(terIDY)₂]Cl₃ complex. Here, “bpy” represents 2,2-bipyridine, “phen” represents 1,10-phenanthroline, and “terpy” represents 2,2′:6′,2″-terpyridine. Examples of the inorganic phosphor may include MgF₂:Eu²⁺ (an absorption wavelength of 300 nm to 400 nm, a fluorescence wavelength of 400 nm to 550 nm), 1.29 (Ba, Ca)O-6Al₂O₃:Eu²⁺ (an absorption wavelength of 200 nm to 400 nm, a fluorescence wavelength of 400 nm to 600 nm), BaAl₂O₄:Eu²⁺ (an absorption wavelength of 200 nm to 400 nm, a fluorescence wavelength of 400 nm to 600 nm), and Y₃Al₅O₁₂:Ce³⁺ (an absorption wavelength of 250 nm to 450 nm, a fluorescence wavelength of 500 nm to 700 nm). Among the phosphors, the inorganic phosphors are preferably used.

Examples of a preferred combination of the first ultraviolet absorber and the second ultraviolet absorber may include a combination of titanium dioxide and zinc oxide. Titanium dioxide is an ultraviolet absorber capable of absorbing light having a wavelength of 411 nm or smaller. In the present invention, the ultraviolet light represents light having a wavelength of 400 nm or smaller. Thus, the first absorption wavelength edge that is the longest wavelength in a wavelength band of ultraviolet light capable of being absorbed by titanium dioxide is 400 nm. Meanwhile, zinc oxide is an ultraviolet absorber capable of absorbing light having a wavelength of 380 nm or smaller.

Thus, the second absorption wavelength edge that is the longest wavelength in a wavelength band of ultraviolet light capable of being absorbed by zinc oxide is 380 nm.

The first ultraviolet absorber may be used alone or in combination of two or more of them at any ratio. The second ultraviolet absorber may be used alone or in combination of two or more of them at any ratio. As each of the first ultraviolet absorber and the second ultraviolet absorber, an ultraviolet absorber except a wavelength-conversion material may be used alone, a wavelength-conversion material may be used alone, and a wavelength-conversion material and an ultraviolet absorber except the wavelength-conversion material may be used in combination.

Each of the first ultraviolet absorber and the second ultraviolet absorber is preferably nanoparticles. The nanoparticles refer to particles having a particle diameter of 0.1 nm or larger and 1,000 nm or smaller. The particle diameter of nanoparticles can be determined under a reflection electron microscope.

When the nanoparticles are used as the first ultraviolet absorber and the second ultraviolet absorber, the formation of the first ultraviolet absorbing layer and the second ultraviolet absorbing layer as layers dispersing the nanoparticles in a binder can lead the first ultraviolet absorbing layer and the second ultraviolet absorbing layer to have refractive indexes controlled by the contained nanoparticles. When the refractive indexes are properly controlled, light can reflect off an interface between the first ultraviolet absorbing layer and another layer in contact therewith, and an interface between the second ultraviolet absorbing layer and another layer in contact therewith. Consequently, light is trapped in the organic photovoltaic cell; thus, it is possible to increase the photovoltaic conversion efficiency.

As necessary, the first ultraviolet absorbing layer and the second ultraviolet absorbing layer may contain a binder in order to hold the first ultraviolet absorber and the second ultraviolet absorber. A preferred binder is a material that can hold the first ultraviolet absorber and the second ultraviolet absorber in the first ultraviolet absorbing layer and the second ultraviolet absorbing layer without significantly impairing the effect of the present invention, and a resin is usually used. Examples of the resin usable as the binder may include a polyester resin, an epoxy resin, an acrylic resin, and a fluorine resin. The binders may be used alone or in combination of two or more of them at any ratio.

The binder is usually used in an amount of 3 parts by weight or more, preferably 5 parts by weight or more, and more preferably 10 parts by weight or more, and is usually used in an amount of 80 parts by weight or less, preferably 50 parts by weight or less, and more preferably 30 parts by weight or less, with respect to 100 parts by weight of the first ultraviolet absorber and the second ultraviolet absorber. The first ultraviolet absorbing layer and the second ultraviolet absorbing layer using the binder in an excessively small amount may unstably hold the first ultraviolet absorber and the second ultraviolet absorber, while the first ultraviolet absorbing layer and the second ultraviolet absorbing layer using the binder in an excessively large amount may insufficiently absorb the ultraviolet light.

The first ultraviolet absorbing layer may contain other components in addition to the first ultraviolet absorber and the binder as long as the effect of the present invention is not significantly impaired. The second ultraviolet absorbing layer may contain other components in addition to the second ultraviolet absorber and the binder as long as the effect of the present invention is not significantly impaired. Examples of the other component may include additives such as another ultraviolet absorber, a filler, and an antioxidant.

The other components may be used alone or in combination of two or more of them at any ratio.

The first ultraviolet absorbing layer and the second ultraviolet absorbing layer usually have a thickness of 1 μm or larger, preferably 10 μm or larger, and more preferably 100 μm or larger, and usually have a thickness of 10,000 μm or smaller, preferably 5,000 μm or smaller, and more preferably 3,000 μm or smaller. The first ultraviolet absorbing layer and the second ultraviolet absorbing layer having an excessively small thickness may insufficiently absorb the ultraviolet light, while the first ultraviolet absorbing layer and the second ultraviolet absorbing layer having an excessively large thickness may excessively increase the thickness of the organic photovoltaic cell.

Examples of the method for forming the first ultraviolet absorbing layer and the second ultraviolet absorbing layer may include a gas phase film formation method, a coating method, and a method of bonding a previously formed film substance. Among them, the first ultraviolet absorbing layer and the second ultraviolet absorbing layer are preferably formed by the coating method because the layers can be readily formed to reduce the cost.

When the first ultraviolet absorbing layer and the second ultraviolet absorbing layer are formed by the coating method, a liquid composition comprising the first ultraviolet absorber and a liquid composition comprising the second ultraviolet absorber are firstly prepared, and a coating process of applying the prepared liquid composition onto a predetermined area is carried out to form the first ultraviolet absorbing layer and the second ultraviolet absorbing layer.

Each of the liquid composition for forming the first ultraviolet absorbing layer and the liquid composition for forming the second ultraviolet absorbing layer usually comprises materials for the first ultraviolet absorbing layer and the second ultraviolet absorbing layer, such as the first ultraviolet absorber, the second ultraviolet absorber, and the binder contained as necessary, and a solvent. When the solvent is contained, the liquid composition may be a dispersion liquid dispersing materials for the first ultraviolet absorbing layer and the second ultraviolet absorbing layer in a solvent and may be a solution dissolving materials for the first ultraviolet absorbing layer and the second ultraviolet absorbing layer in a solvent.

Examples of the solvent contained in the liquid composition for forming the first ultraviolet absorbing layer and the second ultraviolet absorbing layer may include the same solvents as the solvents contained in the liquid composition for forming the active layer. The solvents may be used alone or in combination of two or more of them at any ratio.

In the liquid composition, the solvent is usually contained in an amount of 10 parts by weight or more, preferably 50 parts by weight or more, and more preferably 100 parts by weight or more, and is usually contained in an amount of 100,000 parts by weight or less, preferably 10,000 parts by weight or less, and more preferably 5,000 parts by weight or less, with respect to 100 parts by weight of the first ultraviolet absorber and the second ultraviolet absorber.

After the preparation of the liquid composition for forming the first ultraviolet absorbing layer and the second ultraviolet absorbing layer, the liquid composition is applied onto a predetermined area where the first ultraviolet absorbing layer and the second ultraviolet absorbing layer are intended to be formed. Examples of the coating method of the liquid composition may include coating methods similar to the coating methods of the liquid composition for forming the active layer.

The liquid composition for forming the first ultraviolet absorbing layer and the liquid composition for forming the second ultraviolet absorbing layer are applied to form a film comprising the first ultraviolet absorber and a film comprising the second ultraviolet absorber. Thus, after the application of the liquid compositions, as necessary, a process such as a process of drying the formed film to remove the solvent is performed, and consequently the first ultraviolet absorbing layer and the second ultraviolet absorbing layer are obtained.

### [6. Organic Layer]

The organic photovoltaic cell of the present invention preferably comprises an organic layer containing an organic material between the external ultraviolet absorbing layer and the first electrode. The organic material has excellent flexibility. Thus, the organic layer that is provided between the external ultraviolet absorbing layer and the first electrode can prevent breakage of the organic photovoltaic cell even when stress is generated in the organic photovoltaic cell during heating due to different thermal expansion coefficient between the first electrode and the external ultraviolet absorbing layer. The arrangement of the organic layer can increase the sealing properties and more stably protect the organic photovoltaic cell from external force, oxygen, water, and the like.

The organic layer is preferably in direct contact with the external ultraviolet absorbing layer. Usually, the organic layer has a refractive index different from that of the external ultraviolet absorbing layer; hence, an interface where both are in contact with each other is a face that is likely to reflect light. Thus, when the organic layer is in contact with the external ultraviolet absorbing layer, light internally reflects off the interface. Consequently, light that is applied to the organic Photovoltaic cell of the present invention is trapped in the cell; thus, it is possible to increase the photo voltaic efficiency.

As the organic material comprised in the organic layer, a resin is preferably used. As the resin, various resins such as a thermosetting resin, a thermoplastic resin, and a photocurable resin may be use, and among them, a photocurable resin is preferred. This is because the organic photovoltaic cell does not deteriorate due to heat during the formation of the resin layer. Preferred examples of the resin may include a silicone resin, an epoxy resin, a fluorine resin, and a wax. The organic materials may be used alone or in combination of two or more of them at any ratio.

The organic layer may contain an inorganic material as long as the effect of the present invention is not significantly impaired. In the organic layer, the organic material is usually comprised at a ratio of 50% by weight or more and 100% by weight or less, preferably 75% by weight or more and 100% by weight or less, and more preferably 90% by weight or more and 100% by weight or less in order to stably exert the function of the organic layer.

The organic layer preferably has a thickness of 1 μm or larger and more preferably 5 μm or larger. Such an organic layer can stably exert the function of blocking oxygen and water. The upper limit of the thickness of the organic layer is usually 100 μm or smaller and preferably 10 μm or smaller. The organic layer having an excessively large thickness may be likely to cause defects such as pinholes, voids, and cracks in the organic layer and may cause cracks by thermal expansion of the organic layer when the organic photovoltaic cell is heated.

Examples of the method for forming the organic layer may include a gas phase film formation method, a coating method, and a method of bonding a previously formed film substance. Among them, the organic layer is preferably formed by the coating method because the layer can be readily formed to reduce the cost.

For example, when the organic layer is formed from a resin as the material by the coating method, a fluid resin is firstly prepared, and a coating process of applying the prepared resin onto a predetermined area is carried out to form the organic layer. The resin may contain a component that is not eventually contained in the organic layer, such as a solvent for controlling viscosity.

After the preparation of the fluid resin, the resin is applied. Examples of the coating method of the resin may include the same coating methods as those of the liquid composition for forming the active layer.

The resin is applied to form a film of the resin, and, as necessary, the solvent is dried or the resin is cured by light or heat to form the organic layer.

### [7. Functional Layer]

The organic photovoltaic cell of the present invention may comprise functional layers between the first electrode and the active layer and between the second electrode and the active layer. The functional layer is a layer that can transport the charge generated in the active layer to the electrode. The functional layer between the first electrode and the active layer can transport the charge generated in the active layer to the first electrode, while the functional layer between the second electrode and the active layer can transport the charge generated in the active layer to the second electrode. The functional layer may be provided either between the first electrode and the active layer or between the second electrode and the active layer, and the functional layers may be provided both between the first electrode and the active layer and between the second electrode and the active layer.

The functional layer provided between the active layer and an anode can transport a hole generated in the active layer to the anode, and is also called a hole transport layer or an electron block layer. Meanwhile, the functional layer provided between the active layer and a cathode can transport an electron generated in the active layer to the cathode, and is also called an electron transport layer or a hole block layer. The effective photovoltaic cell of the present invention that comprises the functional layers can increase extraction efficiency of the hole generated in the active layer to the anode, can increase extraction efficiency of the electron generated in the active layer to the cathode, can suppress transfer of the hole generated in the active layer to the cathode, and can suppress transfer of the electron generated in the active layer to the anode. Consequently, the photovoltaic conversion efficiency can be improved.

The functional layer may comprise a material that can transport the charge generated in the active layer. Specifically, the functional layer between the active layer and the anode preferably comprises a material that can transport the hole and that can suppress the transfer of the electron to the functional layer. The functional layer between the active layer and the cathode preferably comprises a material that can transport the electron and that can suppress the transfer of the hole to the functional layer.

Examples of the material for the functional layer may include: halides and oxides of an alkali metal or an alkaline earth metal, such as lithium fluoride; inorganic semiconductors such as titanium dioxide; bathocuproine, bathophenanthroline and a derivative thereof; a triazole compound; a tris(8-hydroxyquinolinate) aluminum complex; a bis(4-methyl-8-quinolinate) aluminum complex; an oxadiazole compound; a distyrylarylene derivative; a silole compound; a 2,2′,2″-(1,3,5-benzenetolyl)-tris-[1-phenyl-1H-benzimidazole] (TPBI) phthalocyanine derivative; a naphthalocyanine derivative; a porphyrin derivative; aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (a-NPD); oxazole; oxadiazole; triazole; imidazole; imidazolone; a stilbene derivative; a pyrazoline derivative; tetrahydroimidazole; polyarylalkane; butadiene; 4,4′,4″-tris(N-(3-methylphenyl)-N-phenylamino)triphenylamine (m-MTDATA);

polyvinylcarbazole; polysilane; and poly(3,4-ethylenedioxidethiophene) (PEDOT). The materials may be used alone or in combination of two or more of them at any ratio.

In the organic photovoltaic cell of the present invention, the functional layer may comprise an ultraviolet absorber. A functional layer serves as the first ultraviolet absorbing layer when the functional layer comprises the first ultraviolet absorber, while a functional layer serves as the second ultraviolet absorbing layer when the functional layer comprises the second ultraviolet absorber. The ultraviolet absorber comprised in the functional layer preferably has a function of transporting a charge and is preferably an inorganic material. Preferred examples of the ultraviolet absorber that meets the condition may include titanium dioxide and zinc oxide. In particular, titanium dioxide is an excellent material because titanium dioxide itself can be used as the material for the functional layer as well as can be used as the ultraviolet absorber. The ultraviolet absorbers may be used alone or in combination of two or more of them at any ratio.

When the functional layer comprises the ultraviolet absorber, the functional layer usually comprises the ultraviolet absorber at a ratio of 25% by weight or more, preferably 50% by weight or more, and more preferably 75% by weight or more in order to block a sufficient amount of ultraviolet light. The upper limit is 100% because an ultraviolet absorber such as titanium dioxide that can transport a charge may be used.

The functional layer may contain other components in addition to the aforementioned materials as long as the effect of the present invention is not significantly impaired.

The other components may be used alone or in combination of two or more of them at any ratio.

The functional layer usually has a thickness of 0.01 nm or larger, preferably 0.1 nm or larger, and more preferably 1 nm or larger, and usually has a thickness of 1,000 nm or smaller, preferably 500 nm or smaller, and more preferably 100 nm or smaller. The functional layer having an excessively small thickness may insufficiently exert the functions of the functional layer, while the functional layer having an excessively large thickness may excessively increase the thickness of the organic photovoltaic cell.

The functional layer may be formed, for example, by a gas phase film formation method, but is preferably formed through a process of applying a liquid composition comprising the material for the functional layer onto a predetermined area because the layer is readily formed to reduce the cost. The method for forming the functional layer from the liquid composition will be described below.

The liquid composition for forming the functional layer usually comprises materials for the functional layer and a solvent. When the solvent is contained, the liquid composition may be a dispersion liquid dispersing the materials for the functional layer in the solvent and may be a solution dissolving the materials for the functional layer in the solvent.

Examples of the solvent contained in the liquid composition for forming the functional layer may include the same solvents as the solvents contained in the liquid composition for forming the active layer. The solvents may be used alone or in combination of two or more of them at any ratio.

In the liquid composition, the solvent is usually contained in an amount of 100 parts by weight or more, preferably 1000 parts by weight or more, and more preferably 10,000 parts by weight or more, and is usually contained in an amount of 1,000,000 parts by weight or less, preferably 100,000 parts by weight or less, with respect to 100 parts by weight of the material of the functional layer.

After the preparation of the liquid composition for forming the functional layer, the liquid composition is applied onto a predetermined area where the functional layer is intended to be formed. Usually, the liquid composition is applied onto a layer (usually, the first electrode, the second electrode, or the active layer) to be in contact with the functional layer in the organic photovoltaic cell of the present invention. Examples of the coating method of the liquid composition may include the same coating methods as those of the liquid composition for forming the active layer.

The liquid composition for forming the functional layer is applied to form a film comprising the material for the functional layer. Thus, after the application of the liquid composition, as necessary, a process such as a process of drying the formed film to remove the solvent is performed, and consequently the functional layer is obtained.

### [8. Other Layer]

The organic photovoltaic cell of the present invention may comprise other layers in addition to the substrate, the first electrode, the second electrode, the active layer, the first ultraviolet absorbing layer, the second ultraviolet absorbing layer, the organic layer, and the functional layer as long as the effect of the present invention is not significantly impaired.

For example, the organic photovoltaic cell of the present invention may comprise a sealer layer. The sealer layer is a layer that protects the organic photovoltaic cell of the present invention from the outside air, moisture, and the like. Usually, the sealer layer is formed as a layer of a sealer that covers the first electrode, the second electrode, the active layer, the first ultraviolet absorbing layer, the second ultraviolet absorbing layer, the organic layer, and the functional layer. Hence, the first electrode, the second electrode, the active layer, the first ultraviolet absorbing layer, the second ultraviolet absorbing layer, the organic layer and the functional layer are usually located in a space formed between the sealer layer and the substrate.

As the sealer, an inorganic sealer may be used and an organic sealer may be used. Examples of the inorganic sealer may include silicon compounds such as silicon oxide, silicon nitride, silicon oxynitride, and silicon carbide; aluminum compounds such as aluminum oxide, aluminum nitride, and aluminum silicate; metal oxides such as zirconium oxide, tantalum oxide, and titanium oxide; metal nitrides such as titanium nitride; and diamond-like carbon. Examples of the organic sealer may include a photocurable resin and a thermosetting resin, and preferred examples may include a silicone resin, an epoxy resin, a fluorine resin, and a wax.

The sealers may be used alone or in combination of two or more of them at any ratio.

The thickness of the sealer layer depends on the type of a sealer, but is usually 1 μm or larger, preferably 5 μm or larger, and usually 10 μm or smaller from the viewpoints of protective performance by the sealer layer, the production cost, and the like.

Examples of the method for forming the sealer layer using an inorganic sealer may include a gas phase film formation methods such as a chemical vapor deposition method (CVD method) and a physical vapor deposition method (PCD method) including a sputtering method and a vacuum deposition method. Examples of the method for forming the sealer layer using an organic sealer may include coating methods such as a spin coating method, a dipping method, a spray method; and a method of bonding a previously formed film substance.

The sealer layer may comprise an additive as necessary. Preferred examples of the additive may include an ultraviolet absorber. When the sealer layer comprises the ultraviolet absorber, the sealer layer can serve as the first ultraviolet absorbing layer or the second ultraviolet absorbing layer to reduce the number of the layers or to reduce the number of production steps for the organic photovoltaic cell, and consequently, the cost reduction can be expected.

The organic photovoltaic cell of the present invention may further include, for example, a water repellent layer on the outermost surface of the organic photovoltaic cell layer, another ultraviolet absorbing layer in addition to the first ultraviolet absorbing layer and the second ultraviolet absorbing layer, and another organic layer on any position in addition to the organic layer between the first electrode and the external ultraviolet absorbing layer.

### Embodiments

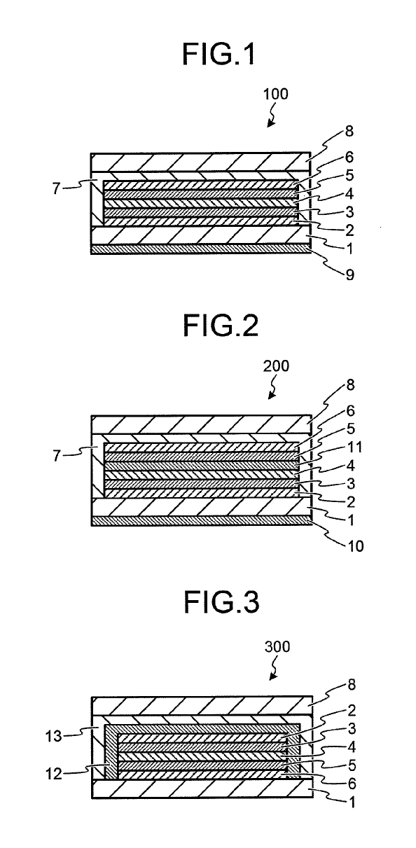

Hereinafter, preferred embodiments of the organic photovoltaic cell of the present invention will be described with reference to drawings. Each of FIG. 1 to FIG. 3 is a schematic cross-sectional view of the organic photovoltaic cell of the embodiment of the present invention. In the below embodiments, the organic photovoltaic cell will be described while the substrate is placed horizontally.

### First Embodiment

An organic photovoltaic cell 100 illustrated in FIG. 1 comprises, on a substrate 1, a first electrode 2 serving as the anode, a functional layer 3 serving as the hole transport layer, an active layer 4 capable of generating a charge by incident light, a functional layer 5 serving as the electron transport layer, and a second electrode 6 serving as the cathode in this order. Each of the first electrode 2 and the second electrode 6 is connected with a terminal not illustrated in the schematic for extracting electricity to the exterior. The first electrode 2, the functional layer 3, the active layer 4, the functional layer 5, and the second electrode 6 are covered with a sealer layer 7 to be sealed except the terminals, and on the sealer layer 7, a substrate 8 is provided. Beneath the substrate 1, an ultraviolet absorbing layer 9 that comprises both the first ultraviolet absorber and the second ultraviolet absorber and that serves as both the first ultraviolet absorbing layer and the second ultraviolet absorbing layer is provided. Thus, the organic photovoltaic cell 100 comprises the ultraviolet absorbing layer 9, the substrate 1, the first electrode 2, the functional layer 3, the active layer 4, the functional layer 5, the second electrode 6, the sealer layer 7, and the substrate 8 in this order.

The organic photovoltaic cell 100 has the structure as described above. Hence, when light is applied from below in the drawing, the applied light passes through the ultraviolet absorbing layer 9, the substrate 1, the first electrode 2, and the functional layer 3 to be input to the active layer 4, thus generating charges in the active layer 4. Among the charges generated in the active layer 4, holes are transported through the functional layer 3 to the first electrode 2, while electrons are transported through the functional layer 5 to the second electrode 6, and each is extracted through the terminals to the exterior. Furthermore, in the organic photovoltaic cell 100 of the present embodiment, ultraviolet light contained in the applied light is blocked by the ultraviolet absorbing layer 9. The ultraviolet absorbing layer 9 comprises the first ultraviolet absorber and the second ultraviolet absorber that can individually absorb ultraviolet light having different wavelength bands, thus being able to block ultraviolet light having a wider wavelength band than that of a conventional ultraviolet absorbing layer. Therefore, the organic photovoltaic cell 100 can effectively suppress the deterioration of an organic material comprised in the active layer 4 due to ultraviolet light to elongate the lifetime of the organic photovoltaic cell 100.

The organic photovoltaic cell 100 of the present embodiment is an example that the electrode near the ultraviolet absorbing layer 9 is the anode and the electrode distant from the ultraviolet absorbing layer 9 is the cathode. However, even when the electrode near the ultraviolet absorbing layer 9 is the cathode and the electrode distant from the ultraviolet absorbing layer 9 is the anode, conversely, the same effect can be obtained.

### Second Embodiment

An organic photovoltaic cell 200 illustrated in FIG. 2 has the same structure as that of the organic photovoltaic cell 100 except that a first ultraviolet absorbing layer 10 comprising the first ultraviolet absorber is provided in place of the ultraviolet absorbing layer 9 and that a second ultraviolet absorbing layer 11 comprising the second ultraviolet absorber and also serving as the functional layer is provided between the active layer 4 and the functional layer 5. Thus, the organic photovoltaic cell 200 comprises the first ultraviolet absorbing layer 10, the substrate 1, the first electrode 2, the functional layer 3, the active layer 4, the second ultraviolet absorbing layer 11, the functional layer 5, the second electrode 6, the sealer layer 7, and the substrate 8 in this order.

The organic photovoltaic cell 200 has the structure as described above. Hence, when light is applied to the organic photovoltaic cell 200, the applied light is input to the active layer 4, thus generating charges in the active layer 4. The charges are extracted from the first electrode 2 and the second electrode 6 through the terminals to the exterior.

Furthermore, for example, when light is applied from below in the drawing, the organic photovoltaic cell 200 of the present embodiment can block ultraviolet light contained in the applied light by the first ultraviolet absorbing layer 10. Moreover, in the organic photovoltaic cell 200, light that is input from below in the drawing may pass through the active layer 4 and may be reflected from the second electrode 6 to be input to the active layer 4 once again. In such a case, ultraviolet light contained in the light that has passed through the active layer 4 can be blocked by the second ultraviolet absorbing layer 11.

Furthermore, for example, when lights are applied from both above and below in the drawing, the ultraviolet light contained in the light applied from below in the drawing can be blocked by the first ultraviolet absorbing layer 10, while the ultraviolet light contained in the light applied from above in the drawing can be blocked by the second ultraviolet absorbing layer 11.

Therefore, the organic photovoltaic cell 200 can effectively suppress the deterioration of an organic material comprised in the active layer 4 due to ultraviolet light to elongate the lifetime of the organic photovoltaic cell 200.

The organic photovoltaic cell 200 of the present embodiment is an example that the electrode near the first ultraviolet absorbing layer 10 is the anode and the electrode distant from the first ultraviolet absorbing layer 10 is the cathode. Conversely, even when the electrode near the first ultraviolet absorbing layer 10 is the cathode and the electrode distant from the first ultraviolet absorbing layer 10 is the anode, the same effect can be obtained.

Furthermore, in the organic photovoltaic cell 200 of the present embodiment, the first ultraviolet absorbing layer 10 is provided on an outside of the first electrode 2, while the second ultraviolet absorbing layer 11 is provided on an inside of the first electrode 2 and the second electrode 6 (a position close to the active layer). Conversely, the second ultraviolet absorbing layer 11 may be provided on an outside of the first electrode 2, while the first ultraviolet absorbing layer 10 may be provided on an inside of the first electrode 2 and the second electrode 6.

### Third Embodiment

An organic photovoltaic cell 300 illustrated in FIG. 3 comprises, on a substrate 1, a second electrode 6 serving as the cathode, a functional layer 5 serving as the electron transport layer, an active layer 4 capable of generating a charge by incident light, a functional layer 3 serving as the hole transport layer, and a first electrode 2 serving as the anode in this order. Furthermore, each of the first electrode 2 and the second electrode 6 is connected with a terminal not illustrated in the schematic. In the organic photovoltaic cell 300, the first electrode 2, the functional layer 3, the active layer 4, the functional layer 5, and the second electrode 6 are covered with the first ultraviolet absorbing layer 12 and the second ultraviolet absorbing layer 13 in this order to be sealed except the terminals, and on the second ultraviolet absorbing layer 13, a substrate 8 is provided. Thus, the organic photovoltaic cell 300 comprises the substrate 1, the second electrode 6, the functional layer 5, the active layer 4, the functional layer 3, the first electrode 2, the first ultraviolet absorbing layer 12, the second ultraviolet absorbing layer 13, and the substrate 8 in this order.

The organic photovoltaic cell 300 has the structure as described above. Hence, when light is applied from above in the drawing, the applied light passes through the substrate 8, the second ultraviolet absorbing layer 13, the first ultraviolet absorbing layer 12, the first electrode 2, and the functional layer 3 to be input to the active layer 4, thus generating charges in the active layer 4. The charges are extracted from the first electrode 2 and the second electrode 6 through the terminals to the exterior. In the organic photovoltaic cell 300 of the present embodiment, ultraviolet light contained in the applied light can be blocked by the first ultraviolet absorbing layer 12 and the second ultraviolet absorbing layer 13. Therefore, the deterioration of an organic material comprised in the active layer 4 due to ultraviolet light can be effectively suppressed to elongate the lifetime of the organic photovoltaic cell 300. Moreover, the first ultraviolet absorbing layer 12 and the second ultraviolet absorbing layer 13 also serve as the sealer layer; thus, the number of layers can be reduced and the number of production steps for the organic photovoltaic cell 300 can be reduced to reduce the cost in comparison with the case of separately providing the sealer layer.

The organic photovoltaic cell 300 of the present embodiment is an example that the electrode near the first ultraviolet absorbing layer 12 and the second ultraviolet absorbing layer 13 is the anode and the electrode distant from the first ultraviolet absorbing layer 12 and the second ultraviolet absorbing layer 13 is the cathode. Conversely, even when the electrode near the first ultraviolet absorbing layer 12 and the second ultraviolet absorbing layer 13 is the cathode and the electrode distant from the first ultraviolet absorbing layer 12 and the second ultraviolet absorbing layer 13 is the anode, the same effect can be obtained.

Furthermore, even when the position of the first ultraviolet absorbing layer 12 is interchanged with that of the second ultraviolet absorbing layer 13, the same effect can be obtained.

### [10. Application of Organic Photovoltaic Cell]

In the manner described above, photoelectromotive force is generated between the electrodes of the organic photovoltaic cell of the present invention by the irradiation of light such as sunlight. The organic photovoltaic cell of the present invention may be used, for example, as a solar cell using the photoelectromotive force. When the organic photovoltaic cell is used as the solar cell, the organic photovoltaic cell of the present invention is usually used as the solar cell for an organic thin film solar cell. The plurality of solar cells may also be integrated to make a solar cell module (organic thin film solar cell module) to be used as the solar cell module. The organic photovoltaic cell of the present invention has long lifetime as described above; therefore, a solar cell comprising the organic photovoltaic cell of the present invention can be expected to have longer lifetime.

The organic photovoltaic cell of the present invention may also be used as an organic optical sensor. For example, when the organic photovoltaic cell of the present invention is irradiated with light while applying electrical voltage between the electrodes or without the application, a charge is generated. Hence, when the charge is detected as a photocurrent, the organic photovoltaic cell of the present invention can serve as the organic optical sensor. The plurality of organic optical sensors may be integrated to be used as an organic image sensor.

### [11. Solar Cell Module]

When the organic photovoltaic cell of the present invention is used as the solar cell to constitute the solar cell module, the solar cell module may basically have the same module structure as that of a conventional solar cell module. The solar cell module generally comprises a supporting substrate, such as a metal and ceramics on which a solar cell is provided. The solar cell is covered with a filling resin, a protection glass, and the like. Hence, the solar cell can take in light through the side opposite to the supporting substrate. The solar cell module may use a transparent material such as a tempered glass as the supporting substrate, on which the solar cell is provided for taking in light through the transparent supporting substrate.

Known examples of the structure of the solar cell module may include module structures such as a superstraight type, a substrate type, and a potting type; and a substrate-integrated module structure used in an amorphous silicon solar cell. The solar cell module using the organic photovoltaic cell of the present invention may appropriately select a suitable module structure depending on an intended purpose, place, environment, and the like.

For example, in the solar cell modules of the superstraight type and the substrate type as typical module structures, the solar cells are arranged at certain intervals between a pair of supporting substrates. One or both of the supporting substrates are transparent and are usually subjected to an anti-reflective treatment. The adjacent solar cells are electrically connected to each other through wiring such as a metal lead and a flexible wire, and an integrated electrode is placed at a periphery of the solar cell module for extracting electric power generated in the solar cell to the exterior.

Between the supporting substrate and the solar cell, a layer of a filler material such as a plastic material including ethylene vinyl acetate (EVA) may be provided as necessary in order to protect the solar cell and to improve the electric current collecting efficiency. The filler material may be previously formed into a film-shape for installing, or a resin may be filled at a desired position and then cured.

When the solar cell module is used at a place where a hard material is not needed for covering the surface, for example, at a place unlikely to suffer from impact from outside, one of the supporting substrate may not be provided. However, the surface without the supporting substrate of the solar cell module preferably has a surface protection layer by, for example, being covered with a transparent plastic film or being covered with a filler resin to be cured for imparting a protection function.

The periphery of the supporting substrate is usually fixed with a metal frame while interposing the solar cell module in order to seal the inside and to secure rigidity of the solar cell module. A space between the supporting substrate and the frame is usually sealed with a sealing material.

The solar cell module can be used while utilizing the advantages of the organic photovoltaic cell because the solar cell module comprises the organic photovoltaic cell of the present invention that is a photovoltaic cell using an organic material. For example, the organic photovoltaic cell can be formed as a flexible cell, and thus when flexible materials are used for the supporting substrate, the filler material, the sealing material, and the like, a solar cell module can be provided on a curved surface.

The organic photovoltaic cell can be produced using a coating method at low cost, and hence the solar cell module can also be produced using the coating method. For example, when a solar cell module is produced using a flexible support such as a polymer film as the supporting substrate, a solar cell is sequentially formed using the coating method and the like while feeding the flexible support from a roll flexible support, the flexible support is cut into a desired size, and a peripheral part of the cut out piece is sealed with a flexible and moisture-proof material to produce a body of the solar cell module. For example, a solar cell module having a module structure so-called “SCAF” described in “Solar Energy Materials and Solar Cells, 48, pp. 383-391” can also be obtained.

The solar cell module using the flexible support may also be bonded and fixed to a curved surface glass and the like to be used.

### EXAMPLES

Hereinafter, the present invention will be specifically described with reference to examples, but the present invention is not limited to the examples described below, and any changes and modifications may be made in the present invention without departing from the gist of the present invention.

### [Evaluation Method]

In Examples and Comparative Examples described below, a square organic photovoltaic cell having a size of 2 mm×2 mm was produced. For the produced organic photovoltaic cell, using CEP-2000 spectral response measurement system manufactured by Bunkoukeiki Co., Ltd., DC voltage application with respect to the cell was swept at a constant rate of 20 mV/second to determine a short circuit current, an open end voltage, and a fill factor (hereinafter, appropriately abbreviated as “FF”), and the determined short circuit current was multiplied by the determined open end voltage and by the determined fill factor to calculate the photovoltaic conversion efficiency.

The produced organic photovoltaic cell was irradiated with sunlight out of doors for 6 hours for an atmospheric exposure test. In the atmospheric exposure test, sunlight was input from the glass substrate side formed with an ITO film to the active layer. After the atmospheric exposure test, the photovoltaic conversion efficiency was determined, and the photovoltaic conversion efficiency measured after the atmospheric exposure test was divided by the photovoltaic conversion efficiency immediately after the production of the organic photovoltaic cell to calculate a photovoltaic conversion efficiency retention.

### Example 1

A glass substrate patterned with an ITO film having a film thickness of about 150 nm as the electrode by a sputtering method was prepared. The prepared glass substrate was washed with an organic solvent, an alkaline detergent, and ultrapure water, then dried, and subjected to ultraviolet light-ozone treatment (UV-O₃ treatment) with an UV-O₃ apparatus.

A suspension of poly(3,4-ethylenedioxythiophene)/poly(styrene sulfonate) (manufactured by H.C. Starck-V TECH Ltd., Bytron P TP AI 4083) was prepared and filtered with a filter having a pore size of 0.5 μm. The filtered suspension was applied onto a surface formed with the ITO film on the glass substrate by spin coating to form a film having a thickness of 70 nm. Then, the film was dried in the atmosphere on a hot plate at 200° C. for 10 minutes to form a functional layer.

Next, an ortho-dichlorobenzene solution comprising a macromolecular compound A being an alternating polymer that was obtained by copolymerization of the monomer represented by Formula (3) and the monomer represented by Formula (4) and that had the repeating unit represented by Formula (5) and [6,6]-phenyl-C₆₁-butyric acid methyl ester (hereinafter, appropriately abbreviated as “[6,6]-PCBM”) at a weight ratio 1:3 was prepared. The macromolecular compound A was 1% by weight with respect to ortho-dichlorobenzene. Then, the solution was filtered with a filter having a pore size of 0.5 μm. The obtained filtrate was applied onto the functional layer by spin coating and then was dried in an N2 atmosphere. Consequently, an active layer having a thickness of 100 nm was obtained. The macromolecular compound A had the weight-average molecular weight of 17,000 in terms of polystyrene and had the number-average molecular weight of 5,000 in terms of polystyrene. The macromolecular compound A had an optical absorption edge wavelength of 925 nm.

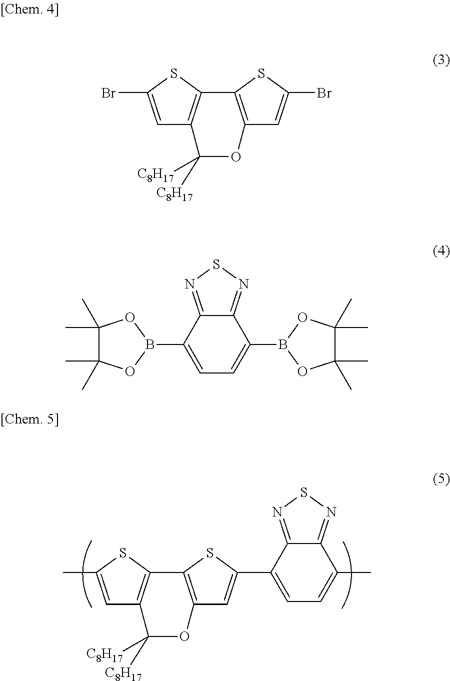

Rutile type titanium dioxide particles (STR-100C-LP, Sakai Chemical Industry Co., Ltd.) was added to ethanol at 3% by weight and the whole was stirred and mixed to prepare a coating solution. The prepared coating solution was applied onto the active layer by a spin coating method and dried at room temperature to form a functional layer having a thickness of 70 nm. The obtained functional layer was a layer also serving as the first ultraviolet absorbing layer (UV cut layer) that was able to absorb light having a wavelength of 411 nm or smaller in the cell.

On the functional layer, an Al film having a thickness of about 70 nm was formed in a resistance heating deposition apparatus to form an electrode.

Onto the electrode, a sealing glass plate was bonded with an epoxy resin (rapid setting type Araldite) as the sealer for sealing treatment.

Then, 14 parts by weight of ZnO particles (manufactured by Sumitomo Osaka Cement Co., Ltd., trade name: ZnO-350, a particle diameter of 10 nm to 30 nm) and 6 parts by weight of an epoxy resin (manufactured by Robnor Resins, trade name: Robnor Adhesives (PX681C/HC)) were mixed with 80 parts by weight of ethanol to prepare a dispersion liquid. The prepared dispersion liquid was applied onto a surface opposite to the ITO film on the glass substrate patterned with the ITO film and dried to form an external ultraviolet absorbing layer that was able to absorb light having a wavelength of 380 nm or smaller and that had a thickness of 100 μm.

In this manner, an organic photovoltaic cell including the external ultraviolet absorbing layer, the glass substrate, the electrode composed of the ITO film, the functional layer, the active layer, the functional layer serving as the first ultraviolet absorbing layer, the functional layer, the electrode composed of Al, the sealer layer, and the sealing glass plate in this order was obtained.

### Example 2

An organic photovoltaic cell was obtained in the same manner as in Example 1 except that the active layer was formed in the manner described below.

The active layer was formed as follows. First, an ortho-dichlorobenzene solution containing poly(3-hexylthiophene) (hereinafter, appropriately abbreviated as “P3HT”) and [6,6]-PCBM at a weight ratio of 1:0.8 was prepared. P3HT was 1% by weight with respect to ortho-dichlorobenzene. Then, the solution was filtered with a filter having a pore size of 0.1 μm. The obtained filtrate was applied onto the functional layer by spin coating and then dried in an N₂ atmosphere. Hence, an active layer having a thickness of 100 nm was obtained.

### Example 3

An organic photovoltaic cell was produced in the same manner as in Example 1 except that the external ultraviolet absorbing layer was formed by applying a coating agent for blocking ultraviolet light (trade name: UV-G13) manufactured by Nippon Shokubai Co., Ltd. so as to have a thickness of 6 μm in place that the epoxy resin layer dispersing ZnO particles was formed. The coating agent for blocking ultraviolet light was an ultraviolet absorber that was able to absorb ultraviolet light having a wavelength of 380 nm or smaller.

### Example 4

An organic photovoltaic cell was produced in the same manner as in Example 2 except that the external ultraviolet absorbing layer was formed by applying a coating agent for blocking ultraviolet light (trade name: UV-G13) manufactured by Nippon Shokubai Co., Ltd. so as to have a thickness of 6 μm in place that the epoxy resin layer dispersing ZnO particles was formed.

### Example 5

The functional layer serving as the first ultraviolet absorbing layer was not formed. Furthermore, a composition comprising a coating agent for blocking ultraviolet light (trade name: UV-G13) manufactured by Nippon Shokubai Co., Ltd. and rutile type titanium dioxide particles (STR-100C-LP, Sakai Chemical Industry Co., Ltd.) at 50:50 (weight ratio) was applied so as to have a thickness of 100 μm to form an external ultraviolet absorbing layer in place that the epoxy resin layer dispersing ZnO particles was formed. An organic photovoltaic cell was produced in the same manner as in Example 1 except for the aforementioned matters.

### Example 6

The functional layer serving as the first ultraviolet absorbing layer was not formed. Furthermore, a composition containing a coating agent for blocking ultraviolet light (trade name: UV-G13) manufactured by Nippon Shokubai Co., Ltd. and rutile type titanium dioxide particles (STR-100C-LP, Sakai Chemical Industry Co., Ltd.) at 50:50 (weight ratio) was applied so as to have a thickness of 100 μm to form an external ultraviolet absorbing layer in place that the epoxy resin layer dispersing ZnO particles was formed. An organic photovoltaic cell was produced in the same manner as in Example 2 except for the aforementioned matters.

### Comparative Example 1

An organic photovoltaic cell was produced in the same manner as in Example 1 except that the functional layer serving as the first ultraviolet absorbing layer was not formed and that the external ultraviolet absorbing layer was not formed.

### Comparative Example 2

An organic photovoltaic cell was produced in the same manner as in Example 2 except that the functional layer serving as the first ultraviolet absorbing layer was not formed and that the external ultraviolet absorbing layer was not formed.

### [Evaluation Result]

Each organic photovoltaic cell produced in Examples 1 to 6 was able to suppress the reduction amount of the photovoltaic conversion efficiency that was reduced with time during the atmospheric exposure test as compared with each organic photovoltaic cell produced in Comparative Examples 1 to 2. That is, each organic photovoltaic cell produced in Examples 1 to 6 had long lifetime. Furthermore, each organic photovoltaic cell produced in Example 3 and Example 4 showed a higher photovoltaic conversion efficiency retention as compared with those in Example 1 and Example 2. That is, each organic photovoltaic cell in Examples 3 and 4 had longer lifetime as compared with that of each organic photovoltaic cell in Examples 1 and 2.

TABLE 1

| | | | | | | | Comparative | Comparative |
|---|---|---|---|---|---|---|---|---|
| | Example 1 | Example 2 | Example 3 | Example 4 | Example 5 | Example 6 | Example 1 | Example 2 |
| Photovoltaic | 89.55 | 51.28 | 94.63 | 65.49 | 76.30 | 55.14 | 71.90 | 34.30 |
| Conversion | | | | | | | | |
| Efficiency | | | | | | | | |
| Retention | | | | | | | | |
| [%] | | | | | | | | |

### INDUSTRIAL APPLICABILITY

The organic photovoltaic cell of the present invention can be used as, for example, a solar cell and a photosensor.

1. An organic photovoltaic cell comprising:
a first electrode;
a second electrode;
an active layer provided between the first electrode and the second electrode and capable of generating a charge by incident light;
a first ultraviolet absorbing layer comprising a first ultraviolet absorber capable of absorbing ultraviolet light having a wavelength not longer than a first absorption wavelength edge; and
a second ultraviolet absorbing layer comprising a second ultraviolet absorber capable of absorbing ultraviolet light having a wavelength not longer than a second absorption wavelength edge having a wavelength shorter by 10 nm or larger than that of the first absorption wavelength edge.

2. The organic photovoltaic cell according to claim 1, wherein the first ultraviolet absorbing layer or the second ultraviolet absorbing layer, the first electrode, the active layer, and the second electrode are arranged in this order.

3. The organic photovoltaic cell according to claim 2, comprising an organic layer comprising an organic material between the first electrode and the first ultraviolet absorbing layer or the second ultraviolet absorbing layer.
